(19) United States
(12) Patent Application Publication
(10) Pub. No.: US 2021/0153345 A1
(43) Pub. Date: May 20, 2021

(54) PROCESS FOR FABRICATING CONDUCTIVE PATTERNS ON 3-DIMENSIONAL SURFACES BY HYDRO-PRINTING

(71) Applicant: Yissum Research Development Company of the Hebrew University of Jerusalem Ltd. Yissum Research, Jerusalem (IL)

(72) Inventors: Shlomo MAGDASSI, Jerusalem (IL); Michael LAYANI, Jerusalem (IL); Gabriel SAADA, Jerusalem (IL)

(73) Assignee: Yissum Research Development Company of the Hebrew University of Jerusalem Ltd., Jerusalem (IL)

(21) Appl. No.: 16/492,003

(22) PCT Filed: Mar. 8, 2018
(86) PCT No.: PCT/IL2018/050275

§ 371 Date: Sep. 6, 2019

Related U.S. Application Data
(60) Provisional application No. 62/469,034, filed on Mar. 9, 2017.

(51) Int. Cl. H05K 1/02; H05K 3/20; H05K 1/09

(52) U.S. Cl. CPC H05K 1/0284; H05K 3/207; H05K 1/0269; H05K 2203/166; H05K 2203/0156; H05K 2203/0531; H05K 1/097

(57) ABSTRACT

Provided is a process for fabricating a conductive pattern on a three-dimensional (3D) object, involving hydroprinting a 2-dimensional (2D) conductive planar pattern on a 2D sacrificial substrate, and transferring the pattern to the 3D object.

### TECHNOLOGICAL FIELD

The invention generally provides a process for hydro-printing a conductive pattern on a 3-D surface.

### BACKGROUND

The field of additive manufacturing has evolved dramatically over the past years, resulting in discoveries of new materials, faster printing methods and novel applications. One research area common to both printed electronics and three-dimensional (3D) printing focuses on digital printing of conductive patterns [1]. Printed electronics applied onto 3D objects can provide new functionalities, such as in meta-materials and 3D antennas or to enable specific electronic features—such as sensors and circuits—onto previously inaccessible structures. This is especially important to the emerging field of internet of things (IoT), when 3D objects are all interconnected.

The main challenge associated with printing conductive patterns onto 3D resides in depositing the conductive material on an uneven, sometimes highly complex topography. The most straightforward approach is using printers with micronozzles, capable of omni-axis movement, such as aerosol printing with a 5-axis system, which requires very costly printing systems and a process that can be conducted on one object only. Extruding a conductive ink through a micronozzle on a 3D object was reported by Lewis et al, who printed antennas on dome shape objects [2-4]. However, this process is time consuming and can be applied to printing a single object facing the nozzle, with a single type of ink, at any time. Another approach is based on a multistep process, involving laser etching, activation and electroless deposition processes (Laser Direct Structuring), however this process can only be used for objects without sharp edges and for deposition of metallic patterns or plastic parts that contain specific activators.

Transfer techniques such as polyimide (PI) and polydimethylsiloxane (PDMS) stamping are also used and are based on making a flexible film with a conductive pattern, and placing this film with the conductor on a 3D object. For example, Rogers et al used a stamping method for transferring sensors onto stretchable substrates (such as balloons and surgical gloves) [5]. Although the stamping resulted in highly stretchable electronics, the transfer method was applied only on curved and slightly curved surfaces, and was unsuitable for multifaceted objects including those with 90° angles, such as cubes. Salvatore et al used polyvinyl alcohol (PVA) as a sacrificial layer for transfer of a transistor. However, the device was fabricated onto a non-sacrificial polymer, Parylene [6], which actually acts as a sticker. Therefore, the Parylene layer, which is an electrical insulator, did not enable transfer of additional circuits that should be electrically connected to the first circuit.

US Patent Application No. 2016/0198577 [8] teaches a process for applying electronics to a 3D object by utilizing an immersion technology to transfer pre-fabricated planar assemblies. The pre-fabricated planar geometries may substantially comply with the envisioned 3D final structure of the application. The pre-fabricated assembly is not formed on the liquid surface in which the immersion occurs.

### BACKGROUND ART

[1] J. Hoerber, J. Glasschroeder, M. Pfeffer, J. Schilp, M. Zaeh, J. Franke, Procedia CIRP 2014, 17, 806.
[2] J. J. Adams, E. B. Duoss, T. F. Malkowski, M. J. Motala, B. Y. Ahn, R. G. Nuzzo, J. T. Bernhard, J. A. Lewis, Adv. Mater. 2011, 23, 1335.
[3] B. Y. Ahn, E. B. Duoss. M. J. Motala. X. Guo. S.-I. Park. Y. Xiong. J. Yoon. R. G. Nuzzo, J. A. Rogers, J. A. Lewis, Science 2009, 323, 1590.
[4] W. Wu, A. DeConinck, J. A. Lewis, Adv. Mater. 2011, 23, 24.
[5] D. H Kim. N. Lu. R. Ghaffari. Y. S. Kim. S. P. Lee. L. Xu. J. Wu. R. H. Kim. J. SongZ. Liu, J. Viventi, B. Graff, B. Elolampi, M. Mansour, M. J. Slepian, S. Hwang, J. D. Moss, S. M. Won, Y. Huang, B. Litt, J. A. Rogers, Nat. Mater. 2011, 10, 316.
[6] G. A. Salvatore, N. Munzenrieder, T. Kinkeldei, L. Petti, C. Zysset, I. Strebel, L. Buthe, G. Troster, Nat. Commun. 2014, 5, 2982.
[7] US Patent Application No. 2016/0198577

### GENERAL DESCRIPTION

Unlike existing art, the invention disclosed herein provides a fabrication method for forming conductive patterns and circuits on multifaceted objects by utilizing hydro-printing (herein “HP”). The process enables printing on any topography, with a variety of active materials and on many objects simultaneously. As such, the process of the invention enables overcoming many of the technological limitations associated with known transfer methods and can actually be performed by printing a pattern on a planar surface and transferring the planar pattern, in a single step, onto a 3D object of any structural complexity, to thereby intimately cover, in accordance with a preformed design, all facets of the 3D object.

The HP process enables fabrication of multiple and overlapping patterns and circuits, avoiding the presence of electrical insulator materials that may have an effect on conductivity. Therefore, the HP enables a sequential process that can be repeated for as many layers as required, as will be further demonstrated herein. This provides a new tool-set for the printed electronics industry, especially for the emerging field of 3D printed electronics. Applications that are expected to benefit from this new process include printed 3D antennas for communications, biomedical devices, 3D electronics and soft robotics, as well as many others.

Unlike HP techniques currently applied, the process disclosed herein utilizes HP of metal, e.g., silver, nanoparticles based inks, or nanostructures of other materials such as carbon, e.g., carbon nanotubes (CNT), graphene, conductive polymers such as PDOT:PSS or polyaniline and quantum dots (QDs) to fabricate electrical circuits onto previously inaccessible objects. The process of the invention enables fabrication of conductive patterns and whole electrical multilayered circuits.

The main advantage of the process of the invention resides in that the hydroprinted pattern is conductive on both sides, making it possible to perform multiple overlapping layers, on any curved shape object. Furthermore, as the pattern is conductive from both sides, it may be brought into contact with the object from either side. The process disclosed in [8] does not provide a pattern that is conductive from both sides, nor a pattern that may be multilayered of structurally complex that is pre-fabricated by printing.

Thus, it is a purpose of the invention to provide a process for fabricating a conductive pattern on a three-dimensional (3D) object, the process comprising printing a 2-dimensional (2D) conductive planar feature-specific pattern on a surface region of a 2D sacrificial substrate (or film), causing said sacrificial substrate (or film) to decompose and contact-transferring said conductive pattern to a surface region of the 3D object such that the 2D conductive pattern aligns with features on the surface region of the 3D object.

In some embodiments of methods of the invention, the printing or patterning steps may be repeated once or more times after the first printing or patterning step. In some embodiments, each printing or patterning step may be repeated at least twice, three times, four times, and so on.

The process for fabricating a conductive pattern on a three-dimensional (3D) object may be repeated more than one time to thereby contact-transfer one or more patterns onto the same 3D object. The one or more additional patterns to be transferred to the 3D object may be the same or different from the first pattern. Where the patterns transferred are different from one another, the difference may be in structure, structure features and layout or complexity, material composition, conductivity, etc. The additional patterns to be transferred may be transferred onto the same surface region of the 3D object or to other regions thereof. The patterns may overlap one another or may be spaced apart. For example, a process of the invention may comprise:
printing a 2-dimensional (2D) planar feature-specific pattern on a surface region of a 2D sacrificial substrate (or film), causing said sacrificial substrate (or film) to decompose and contact-transferring said pattern to a surface region of the 3D object;
printing another 2-dimensional (2D) planar feature-specific pattern on a surface region of a further 2D sacrificial substrate, causing said further sacrificial substrate to decompose and contact-transferring said pattern to a surface region of the same 3D object; and
optionally repeating the printing step(s) one or more additional times;

such that at least one of the patterns is conductive and the pattern(s) aligns with features on the surface region of the 3D object.

The printing step may be used to hydroprint a conductive or non-conductive pattern, as long as the transferred pattern is eventually rendered conductive. In other words, each printing step or cyclic may comprise a step of printing a conductive pattern or printing a non-conductive pattern that is subsequently rendered conductive.

In some embodiments, the process comprises:
printing on a 2D sacrificial substrate (or film) a conductive pattern having a layout alignment of surface features to a surface region of a 3D object to be associated (or coated) with said pattern; said conductive pattern comprising at least one conductive material, e.g., selected from sintered metal nanoparticles, carbon nanotubes (CNT), graphene, conductive polymers and quantum dots (QDs);
placing the printed sacrificial substrate onto a surface of a liquid (or causing the printed substrate to float on the liquid surface), the liquid being selected to interact with the sacrificial substrate and cause its dissolution or decomposition, such that the conductive pattern remains intact on the surface of the liquid; and
contacting said conductive pattern with the 3D object permitting the conductive pattern to three-dimensionally align and associate with its surface.

In some embodiments, the process comprises obtaining a sacrificial substrate and printing thereon a pattern, the pattern having a layout enabling alignment of surface features to a surface region of a 3D object to be associated (or coated) with said pattern. In some embodiments, the pattern is a non-conductive pattern and the invention further comprises sintering the non-conductive pattern under conditions permitting coalescence of the non-conductive material, rendering the pattern conductive.

Where the pattern is formed of a material selected from, e.g., non-sintered metal nanoparticles, carbon nanotubes (CNT), graphene, conductive polymers (such as PDOT:PSS, polyaniline and others) and quantum dots (QDs), or any other conductive material, sintering may not be required. In such cases, the process may not comprise a sintering step.

The liquid on the surface of which the substrate is placed may be contained in a vessel, a container or a bath, such that the most exposed surface of the liquid has a large enough surface area to hold the printed sacrificial substrate in a flat form. The printed substrate is allowed to float on the liquid surface. The liquid may be chosen as disclosed herein and may be selected from water and organic solvents or liquids. As the printed substrate must be allowed to float on the surface of the liquid, the density and surface tension of the liquid may be modified to achieve substrate floating. In some embodiments, the liquid is water. Depending on the processing steps, the constitution of the sacrificial substrate, the rate of its decomposition, and other parameters, the liquid, e.g., water, may be enriched or mixed with (or may be depleted of) one or more additives selected to modify or modulate any one parameter associated with, inter alia, the decomposition rate of the sacrificial substrate and constitution of the pattern. For example, where sintering of a metallic pattern is achieved in the presence of halide ions, the volume of water on the surface of which the patterned substrate is placed may be enriched with metal halide salts. Alternatively, in cases where the presence of metal ions or halide ions in the water volume is to be minimized, a chelating agent or a purified volume of water may be used. Thus, additives that may be added include, for examples, soluble salts, co-solvents, surfactants, alcohols, chelating agents, stabilizers, agents modifying surface tension, and others.

Thus, the process of the invention comprises:
printing on a 2D sacrificial substrate (or film) a non-conductive pattern having a layout alignment of surface features to a surface region of a 3D object to be associated (or coated) with said pattern;
causing said non-conductive pattern to be conductive;
placing the printed sacrificial substrate onto a surface of a liquid (or causing the printed substrate to float on the liquid surface), the liquid being selected to interact with the sacrificial substrate and cause its dissolution or decomposition, such that the conductive pattern remains intact on the surface of the liquid; and
contacting said conductive pattern with the 3D object permitting the conductive pattern to three-dimensionally align and associate with its surface.

Alternatively, the process of the invention comprises:
printing on a 2D sacrificial substrate (or film) a non-conductive pattern having a layout alignment of surface features to a surface region of a 3D object to be associated (or coated) with said pattern;
placing the printed sacrificial substrate onto a surface of a liquid (or causing the printed substrate to float on the liquid surface), the liquid being selected to interact with the sacrificial substrate and cause its dissolution or decomposition, such that the conductive pattern remains intact on the surface of the liquid;
prior to complete dissolution or decomposition, causing said non-conductive pattern to be conductive; and
contacting said conductive pattern with the 3D object permitting the conductive pattern to three-dimensionally align and associate with its surface.

In accordance with the invention, sintering may be achieved by treating the non-conductive pattern with a sintering agent or under sintering conditions when the patterned substrate is not floating on the liquid surface, or when the patterned substrate is on the liquid surface and/or optionally obtain final sintering after the pattern was formed on the 3D object. Sintering, as will be further disclosed herein, may be achieved by exposing the non-conductive pattern to a sintering agent, to sintering conditions, or by exposing the non-conductive pattern to an agent present (dissolved) in the liquid medium, e.g., an ion, a salt or any other agent, as disclosed herein.

The “sacrificial substrate or film”, onto which a pattern is initially formed, is a 2D substrate or film made of a material which upon (completion of) patterning is caused to be substantially completely or completely consumed or dissolved or destroyed without affecting the integrity or structure of the pattern (conductive or yet to be conductive) formed thereon. The sacrificial substrate is typically a film or a solid material that is dissolvable or consumable or destroyed when coming into contact with at least one liquid, and which is otherwise solid and capable of receiving a pattern thereon. The rate at which the solid material is dissolved or consumed or destroyed by the at least one liquid may be tailored or selected based on the sequence of steps utilized, the pattern to be formed, the thickness of the substrate, the type of substrate material, and other parameters known to the practitioner. The material of the sacrificial substrate may thus be selected from a variety of materials or compositions, such as polymers, water-soluble materials, organic liquid soluble solids, ionic materials and others. In some embodiments, the sacrificial substrate is or comprises a water soluble material and the at least one liquid may thus be water or a medium containing water. Similarly, where the sacrificial substrate is of a material soluble in an organic liquid, the at least one liquid may be an organic liquid or a medium containing such a liquid.

The sacrificial substrate is selected not to chemically interact with the printed pattern or any material contained within the ink formulation used for the printing of the pattern.

In some embodiments, the substrate is selected amongst heat-sensitive plastic substrates. In further embodiments, the heat-sensitive plastic substrates are water-soluble.

In some embodiments, the sacrificial substrate is composed of a water-soluble material, e.g., polymer. In some embodiments, the sacrificial substrate is of a material selected from poly(N-isopropylacrylamide) (PNIPAM); polyacrylamide (PAM); poly(2-oxazoline); polyethylenimine (PEI); poly(acrylic acid); polyacrylates, e.g., polymethacrylate; poly(ethylene glycol); poly(ethylene oxide); poly(vinyl alcohol) (PVA); poly(vinylpyrrolidone) (PVP); polyelectrolytes; cucurbit[n]uril hydrate; maleic anhydride copolymers; polyethers; poly(methyl methacrylate) (PMMA); polysaccharides such as sodium alginate, calcium alginate, nanocellulose, hydroxyethyl cellulose, hydroxy propyl methyl cellulose, carboxy methyl cellulose, sugars and maltodextrins; proteins such as bovine serum albumin and gelatin; and copolymers or mixtures of any two or more of the aforementioned.

In some embodiments, the sacrificial substrate is a PVA substrate.

In accordance with the invention, the patterning of the sacrificial substrate may be achieved in advance of the process and the printed substrate may be stocked or stored for any period of time under conditions preventing its dissociation or decomposition (e.g., where the substrate is hydrophilic, it may be stored under anhydrous conditions). Alternatively, the pattern may be formed while the substrate is laid on a surface of the liquid, such that printing is completed prior to the time when the substrate decomposes. In some embodiments, the printing is achieved while the substrate is not in contact with a dissolving liquid and the printed substrate is laid on the liquid or in a solid surface within the liquid only after printing has been completed.

Thus, the process of the invention may comprise printing on a 2D sacrificial substrate (or film) a non-conductive pattern having a layout alignment of surface features to a surface region of a 3D object to be associated (or coated) with said pattern; the printing is performed while the substrate is optionally on a surface of a liquid.

In some embodiments, a bare substrate is placed on a surface of a liquid and the pattern is thereafter formed.

The 2-dimensional (2D) “planar feature-specific pattern”, which may or may not be conductive when formed on a surface region of the sacrificial substrate, may be a line pattern, a line matrix pattern, a crisscross pattern, a single layered pattern or a multilayered pattern, of any shape and size, that has a layout structure suited to come in contact with the 3D object from either of the pattern faces (namely from the pattern top side or from its bottom side). In some embodiments, the pattern is transparent. The layout is engineered or selected or formed to precisely align surface features and textures (thus being “feature specific”) of the 3D object; thus any feature of the 2D pattern may be tailored to be maintained or modified when on the surface of the 3D object. In some cases, the 2D pattern may be such that only upon adherence onto the surface of the 3D object, the full pattern evolves, e.g., a cyclic pattern is formed. The layout may be computed and printed based on any computational printing algorithm or model that enables such precise alignment of the surface features and textures to match complex 3D surfaces. In particular, the printed pattern layout may be generated by a simulating hydrographic printing process, such that when the pattern is applied onto the surface of a sacrificial substrate and the 3D object is brought into contact therewith, the pattern adheres to the object, follows its contour and wraps around its surface, permitting any feature that is part of the printed pattern to become associated with a pre-determined and pre-defined region or feature on the surface of the object. Unlike a pattern that forms on the object following adherence, the pattern formed on the surface of the sacrificial substrate is planar. An exemplary methodology for achieving a layout having a precise alignment to a surface of a 3D object is provided in Zhang Y, et al., Computational Hydrographic Printing, ACM Transactions on Graphics, 34, No. 4, Article 131 (2015).

Based on a predetermined layout printing scheme, the pattern may be formed on the substrate by any printing technique known in the art. For example, the pattern may be formed by nonimpact printing, e.g., ink-jet printing. The ink-jet technology which may be employed in a process according to the invention for depositing ink or any component thereof onto a sacrificial substrate, may be any ink-jet technology, including thermal ink-jet printing, piezoelectric ink-jet printing and continuous ink-jet printing.

In accordance with the invention, the pattern is obtained by applying an ink formulation, e.g., by ink-jetting the formulation, on the surface region of the sacrificial substrate. The ink formulation comprises a liquid carrier and a material to be jetted, e.g., a plurality of metallic nanoparticles, or an already conductive material, or any other nanoparticulate material, such as CNT, QD and graphene, and any other additive that may be necessary for achieving a stable formulation or an efficient patterning.

Where the ink formulation comprises metallic nanoparticles, the formulation may comprise a single metal population or a mixed population of different nanoparticles or nanoparticulate materials, the materials being different in, e.g., constitution (metal, doped or undoped), shape and/or size. In some embodiments, the pattern is a metallic pattern formed of a plurality of metal nanoparticles.

Metal nanoparticles are solid particles of at least one metal, having at least one dimension in the nanometer scale, i.e., an average size of between 0.1 and 500 nm. In some embodiments, the metallic nanoparticles have a particle size in the range of 0.1 and 5 nanometers, 1 and 10 nanometers, 10 and 30 nanometers or 10 and 100 nanometers. In some embodiments, the metallic nanoparticles have a particle size in the range of 1 and 100 nanometers.

In some embodiments, the metallic nanoparticles have a particle size of between 1 and 100 nanometers. In some other embodiments, the metallic nanoparticles have a particle size of between 10 and 40 nanometers. In some embodiments, the metallic nanoparticles have a particle size of between 10 and 20 nanometers. In some embodiments, the metallic nanoparticles have a particle size of between 1 and 1,000 nanometers. In some other embodiments, the metallic nanoparticles have a particle size of between 100 and 1,000 nanometers. In some embodiments, the metallic nanoparticles have a particle size of between 200 and 1,000 nanometers. In some embodiments, the metallic nanoparticles have a particle size of between 300 and 1,000 nanometers. In some other embodiments, the metallic nanoparticles have a particle size of between 400 and 1,000 nanometers. In some embodiments, the metallic nanoparticles have a particle size of between 500 and 1,000 nanometers. In some embodiments, the metallic nanoparticles have a particle size of between 600 and 1,000 nanometers. In some other embodiments, the metallic nanoparticles have a particle size of between 700 and 1,000 nanometers. In some embodiments, the metallic nanoparticles have a particle size of between 800 and 1,000 nanometers. In some embodiments, the metallic nanoparticles have a particle size of between 900 and 1,000 nanometers.

In some embodiments, the metallic nanoparticles have a particle size of between 1 and 100 nanometers. In some other embodiments, the metallic nanoparticles have a particle size of between 10 and 100 nanometers. In some embodiments, the metallic nanoparticles have a particle size of between 20 and 100 nanometers. In some embodiments, the metallic nanoparticles have a particle size of between 30 and 100 nanometers. In some other embodiments, the metallic nanoparticles have a particle size of between 40 and 100 nanometers. In some embodiments, the metallic nanoparticles have a particle size of between 50 and 100 nanometers. In some embodiments, the metallic nanoparticles have a particle size of between 60 and 100 nanometers. In some other embodiments, the metallic nanoparticles have a particle size of between 70 and 100 nanometers. In some embodiments, the metallic nanoparticles have a particle size of between 80 and 100 nanometers. In some embodiments, the metallic nanoparticles have a particle size of between 90 and 100 nanometers.

Where the nanoparticles are generally in the form of nanospheres, the particle size refers to the diameter of the spheres. Where the nanoparticles are not in the form of a sphere, the particle size refers to the particles shortest dimension.

The nanoparticles may be of any shape or form including, but not limited to, nanorods, spherical particles, nanowires, nano-sheets, quantum dots, and core-shell nanoparticles.

The metallic nanoparticles may be composed of any metallic material. In some embodiments, the nanoparticles are composed of a metal selected from metals of Groups IIIB, IVB, VB, VIB, VIIB, VIIIB, IB or IIB of block d of the Periodic Table of Elements. In other embodiments, said metallic nanoparticles are selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Al, Sn, In, Ga and Ir.

In some other embodiments, said metallic nanoparticles are selected from Cu, Ni, Ag, Au, Pt, Pd, Al, Fe, Co, Ti, Zn, In, Sn and Ga. In yet other embodiments, said metallic nanoparticles are selected from Cu, Ni and Ag nanoparticles. In some embodiments, said metallic nanoparticles are selected from Ag and Cu nanoparticles. In other embodiments, the metallic nanoparticles or microparticles are Ag nanoparticles.

In some embodiments, the pattern is formed of any conductive material, which may or may not be metallic or containing a metal.

Once a pattern is formed on the sacrificial substrate, and for applications wherein the pattern is to be rendered conductive, the process further comprises a step of rendering a metallic pattern continuous and electrically conductive. This is achieved by sintering the metal nanoparticles in the pattern in order to render the pattern conductive. The sintering may be achieved by exposing the non-conductive pattern to a sintering agent, to sintering conditions or to a liquid medium comprising an agent that is capable of sintering the pattern upon dissolution or composition of the sacrificial substrate.

In some embodiments, sintering is achieved by any low temperature sintering process, such as low temperature thermal sintering, laser sintering, chemical sintering, plasma sintering or photonic sintering. In some embodiments, low temperature thermal sintering is achieved at a temperature sufficient to cause sintering, without affecting or accelerating early decomposition of the sacrificial substrate. The sintering may be performed while the substrate is placed on a surface of a liquid or preformed prior to placing the substrate on the liquid surface. In some embodiments, low temperature sintering is typically at room temperature (23-30° C.), or at temperatures below 50° C.

In some embodiments, at least one sintering agent may be used for achieving or accelerating efficient sintering. In some embodiments, sintering with at least one sintering agent is carried out at room temperature (23-30° C.).

The sintering agent may be an agent capable of coalescing the nanoparticles under specified conditions. The sintering agent may be selected, in a non-limiting way, amongst salts, e.g., agents containing chloride ions such as KCl, NaCl, MgCl₂, AICl₃, LiCl and CaCl₂); organic or inorganic acids, e.g., HCl, H₂SO₄, HNO₃, H₃PO₄, formic acid, acetic acid, acrylic acid; and organic or inorganic bases, e.g., ammonia, organic amines (e.g., aminomethyl propanol (AMP)), NaOH and KOH. In some embodiments, the sintering agent is NaCl.

In some embodiments, sintering is achievable at a temperature lower than 130° C. In other embodiments, sintering is affected at room temperature or at a temperature lower than 120, 110, 100, 90, 80, 70, 60, 50, 40 or 30° C. In some embodiments, sintering is achieved at a temperature below 50 or below 40 or below 30° C.

As a pattern formed on a sacrificial substrate may be formed of multiple crossing lines or patterns, thus forming on certain regions multilayers of metallic nanoparticles, sintering of the nanoparticles may be carried out after each printing step, or after printing multiple layers or after the full pattern has been formed.

The printed or formed pattern may take on any shape and size and may be predetermined or random. The pattern may be a single continuous line pattern or a more complex structure comprising line junctions and multiple layers. Notwithstanding the type of pattern, it may be conductive from both ends. In some embodiments, the pattern is a pattern of an electronic circuit.

In a process of the invention, the sintering step may be carried out after the pattern has been formed on the 2D substrate. In some embodiments, the process comprises:
forming on a 2D sacrificial substrate a pattern, as disclosed herein; optionally sintering said pattern;
placing the optionally sintered printed sacrificial substrate onto a surface of a liquid; and optionally sintering said pattern (in case not sintered prior thereto);
causing the sacrificial substrate to dissolve or decompose and detach from the pattern, thereby keeping the pattern afloat on the surface of the liquid; and
contacting said floating pattern with the 3D object permitting the pattern to three-dimensionally align and associate with its surface.

In other embodiments, the process comprises:
placing a bare (not patterned) sacrificial substrate onto a surface of a liquid;
patterning said bare sacrificial substrate to obtain a patterned substrate;
sintering said pattern;
causing the sacrificial substrate to dissolve or decompose and detach from the pattern, thereby keeping the pattern afloat on the surface of the liquid; and
contacting said floating pattern with the 3D object permitting the pattern to three-dimensionally align and associate with its surface.

The contacting of the 3D object and the floating pattern may be from the top (from the outside of the liquid vessel) or from the bottom (from within the vessel). In some embodiments, the 3D object is brought into contact with the pattern from above the water surface and is permitted to fully interact with the pattern so that the pattern fully adheres to the object. The orientation (point(s) of contact, angle, etc) according to which the object is brought into contact may be easily determined by the practitioner. Alternatively, prior to placing the optionally patterned sacrificial substrate on the surface of the liquid, the 3D object is placed within the vessel. Once the pattern is formed and the sacrificial substrate has been dissolved or decomposed, the liquid volume may be reduced (e.g., by any means available for emptying a liquid within a vessel), at a rate causing the pattern to slowly come into contact with the object. As the liquid levels continues to drop, the rate may be optionally reduced, to cause complete adherence of the pattern to the object.

The patterned object may be post-treated, e.g., to endow the pattern with additional features or elements that cannot be printed. Such features or elements may be wirings, coatings, etc. The post-treatment stage may also involve drying of the formed pattern and subsequent additional washings to render the pattern free of any material composed in the sacrificial substrate. For example, where the pattern is conductive, the object is dried following fabrication and subsequently washed in water to dissolve minute amounts of PVA that may be present. In some embodiments, post-treatment involves contacting the patterned object with a sintering agent or under sintering conditions to render the pattern conductive or to improve conductivity.

The invention further provides a 3D object having at least one surface region thereof coated with a conductive pattern formed by HP. The 3D object may be any object having an irregular or non-flat shape that includes one or more angles or curvatures or which may have a complex shape. The 3D object may have a plurality of faces, or sides, each face arranged at an angle to another face. The pattern may not be formed on the full surface of the 3D object, but may be functionally formed on any region of the object.

In other embodiments, the transferred pattern can be a whole thin-film device, such as a solar cell, electronic circuit including components such as transistors, OLED, LED, RFID tag with a chip, electrical heater, sensor, radiation absorbing structures, electroluminescent device, “E skin” and others.

The 3D object may be an object or an element used in the electronic, optical or opto-electronic fields. Such objects elements may be selected from electronic component such as resistors, inductors, capacitors, solid state light sources, sensors, solar cells, solid state power storage devices, wirings, lenses and others.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-E schematically demonstrates electronic printing using the hydro-printing method. In an exemplary embodiment of the invention: (A) PVA film with conductive pattern on water (top view), (B) After PVA elimination, the conductive pattern floats on the water (top view), (C) 3D object is immersed into the water (side view), (D) Conductive pattern is fully adhered to the 3D object (side view), (E) hydroprinted object after washing from PVA residues.

FIGS. 2A-D schematically depicts a water level lowering method, in which (A) Printed pattern on PVA is fixed on the water surface, (B) After PVA dissolution, the water is pump out of the tank, (C) Water level is lowered until the Ag pattern makes contact with the object. The pattern mimics the object geometry (D).

FIGS. 3A-G provide images of conductive silver lines transferred onto: (A) Different-sized domes (B) 90° angled cubes (C) Spheres made of (left to right): epoxy, acrylate (half matte and half glossy), gypsum and glass (not printed), (D) Electric circuit transferred onto a wave like object (E) Electric circuit shaped as HUH transferred onto a dome structure (F) Heater device transferred onto a glass sphere (G) Temperature of 87.4° C. was achieved by providing 50 volt to the spiral pattern. For samples with several un-connected lines, additional coating with PVB may be required.

FIGS. 4A-B show three lines, conductive on both sides, hydroprinted separately in three different steps. The silver lines overlap at the square shaped edges to ensure conductivity from end to end.

FIGS. 5A-D depict: (A) NFC tag hydroprinted onto a dome. To prevent short-circuit, a few drops of isolating polymer solution were casted on the internal loops leaving the coil's terminals uncovered, (B) Coil's terminals connected by secondary hydroprinting of a conductive bridge, (C) Illustration of bridge hydroprinting (D) A 250 μm line width forming a 12 coils NFC 13.56 MHz antenna hydroprinted onto a dome, connected to a commercial 144 bytes Ntag203 chip using silver paste.

FIGS. 6A-D present: (A) The correlation between line resistance and number of printed layers at various printing resolution (400, 500, and 600 DPI, identified by a square, rhombus, and triangle, respectively). Each resistance value was measured for three hydroprinted samples at a constant length of 1 cm. (B) Electrical resistance in hydroprinted samples while the process is conducted at various concentrations of NaCl. Each measurement was conducted for 3 samples at a constant length of 1 cm. (C) Ag NPs before sintering, (D) Ag NPs sintered in 1.5 wt % NaCl solution; necking between the particles and showing possible presence of NaCl particles.

FIG. 7 depicts Ag NPs thickness analysis by FIB. The sample (five layers at 600 DPI) was coated with 2 layers of platinum. It was found that the sample average height was 864 nm (±12.8).

FIGS. 8A-B show (A) Silver nano wires conductive line hydroprinted onto a finger of nitrile glove, (B) CNT conductive line hydroprinted onto ABS dome.

### DETAILED DESCRIPTION OF EMBODIMENTS

A conductive pattern according to the invention is printed on a flat substrate by conventional printers. Typically while fabricating 2D conductive patterns composed of metal nanoparticles (NPs), a sintering process is required, typically performed at high temperatures. However, with heat sensitive substrates, such as PVA exemplified by the present approach, elevated temperatures may cause deformation of the substrate, and only low-temperature processes should be performed. Such may include photonic, plasma, laser and chemical sintering.

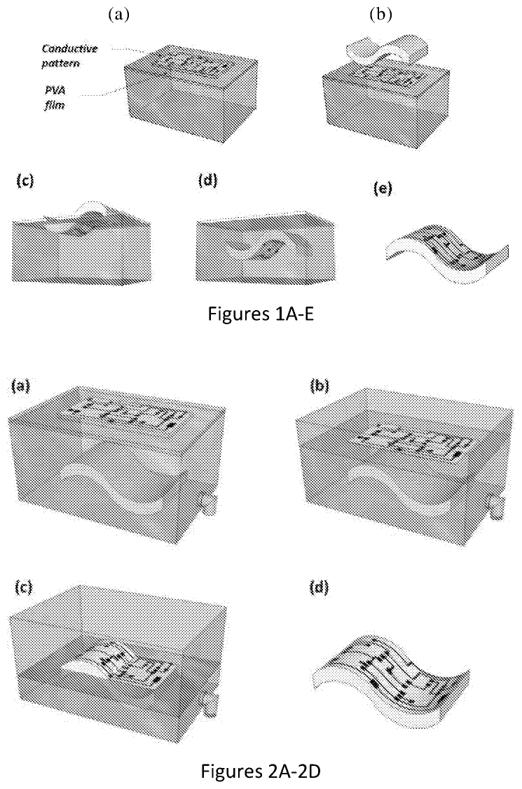

For example, silver NP-based inks undergo sintering at room temperature by exposure to HCl vapor, yielding continuous conductive patterns. When the silver ink is exposed to negatively charged chloride ions, the latter replace the physically bonded stabilizer on the surface of the silver NPs, thus allowing them to form necks that later overlap and sinter. This unique property enables inkjet printing of functional conductive patterns on heat-sensitive plastic substrates, such as polyvinyl alcohol (PVA). For the first step of the process, a conductive pattern was printed on a PVA substrate. PVA is water soluble. Subsequent to printing, a chemical sintering process was performed at room temperature. An exemplary process scheme is presented in FIG. 1. In the next step, the PVA film with the printed pattern facing upwards is placed at the air-water interface of a hot (50° C.) deionized water bath (FIG. 1A), leading to dissolution of the PVA film, while the printed conductor remains intact. The film dissolution time can vary between a few seconds to many minutes, and depends on various parameters such as film thickness, type and concentration of plasticizers, polymer molecular weight, and immersion bath temperature. The film properties were optimized to enable dissolution within less than 2 minutes, for films with an average thickness of 35 μm.

As schematically shown in FIG. 1B, following placement of the film on the water surface and its dissolution, the object is immersed into the water while passing through the pattern which lies on the water surface. It was observed that once an initial contact is made between the printed pattern and the object, the entire pattern sticks to the surface of the object, following its topography, no matter how complex it was. After the whole printed pattern is placed on the object, in a process which takes only a few seconds, the object is removed from the water and left to dry. In the final step, all PVA residues are washed off.

An alternative sequence is depicted in FIGS. 2A-D.

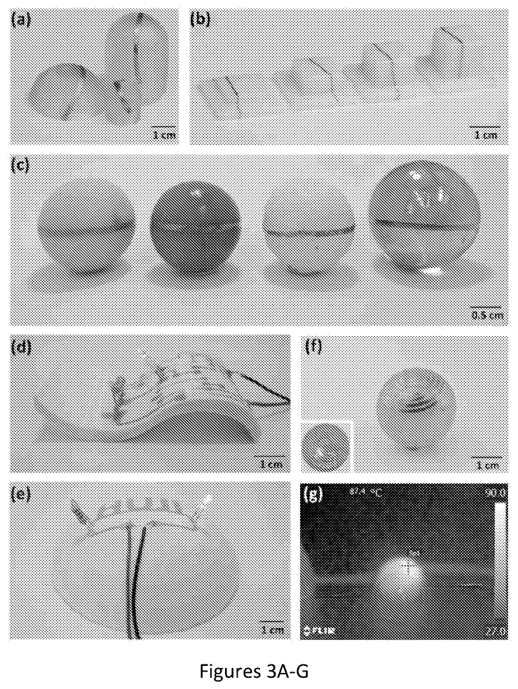

To show the versatility of the method, objects were fabricated composed of various materials, by 3D-printing (by plastics and ceramic printers, excluding the glass sphere), some with 90-degree angles and some with round shapes. FIGS. 3A-C show variously sized and shaped objects: domes, cube-shaped steps and spheres. Silver conductive lines were hydroprinted on all these shapes, yielding continues lines which were conductive in their entirely, without damaging the original dimensions of the printed patterns. Overall, it was found that the process was suitable for object structures made of epoxy, acrylate (both smooth and rough), gypsum and glass (FIG. 3C). A remarkable finding was the printing over the 90-degree angles, which is impossible to achieve with simple direct printers and so rapidly. The hydro-printing onto the 90°-angle steps which is shown in FIG. 3B was performed by lowering the water with the floating PVA film rather than by immersing the object into the water as in all the other demonstrations. The resolution of the hydroprinting is mainly defined by the resolution of the printing process. A significant change was not noticed in the dimensions of the printed lines, after the hydroprinting process, probably since the lines were sintered. Having said that, it could be that with very complex topologies some mis-alignment may occur. The resolution of hydroprinted patterns should be defined mainly by the printing technology of the conductive pattern on the film. With the 10 picolitter Dimatix printhead a line width of 133 μm was obtained. It should be noted that for these printed samples, some deterioration in conductivity may occur, for example printed lines (167±10 μm) having an average resistance of 0.66±0.26Ω, at first stage and 1.32±0.16Ω after hydroprinting. This range of line widths is relevant to a variety of applications including near field and Bluetooth antennas.

The possibility to hydroprint an electrical circuit, which consist of several free-standing lines, was investigated as well, by a single step as shown in FIGS. 3D-E. In FIGS. 3D-E, the hydroprinted electrical circuits were provided on curved surfaces, which were assembled with an LED and a resistor. Further performed was hydro-printing of an electrical heater onto a glass sphere (FIGS. 3F-G), which shows that hydroprinted patterns can withstand high temperatures.

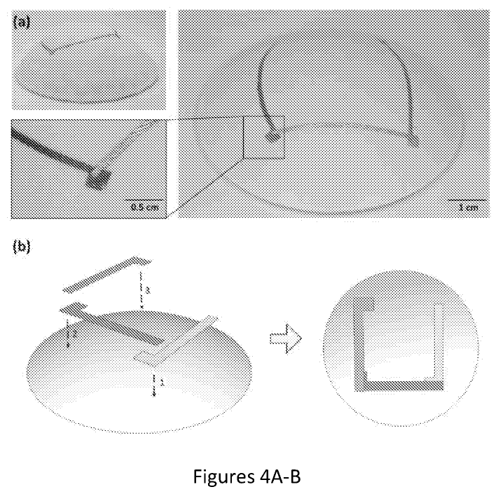

It was found that the hydro-printing method is also suitable for fabrication of multilayer circuits, simply by repeating the process as many layers as required, as shown in FIG. 4. This result emphasizes the novelty of using hydroprinting method, which enables fabricating of overlapping circuits, since there is no insulating layer. The resulting circuit is constructed from three separate conductive lines (12.4, 41.6 and 6.0Ω respectively) and resulted in an overlapping circuit having a resistance from edge-to-edge. This result shows that there are no insulating PVA residues, which remain after the hydroprinting.

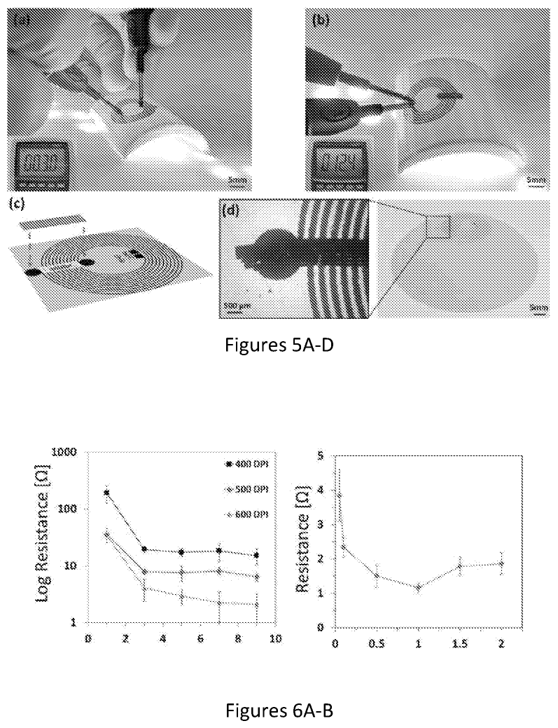

In order to further show the applicability of multilayer hydroprinting, a near field communication (NFC) antenna was fabricated which was hydroprinted onto a dome structure (FIG. 5). This antenna was hydroprinted in two stages as shown in FIG. 5C. At first, the circular coil was hydroprinted on the dome, followed by hydroprinting of a conductive bridge, which connected the two coils edges. In order to prevent short-circuit of the coil due to the bridge connector, a PVB insulator was placed onto the inner coil circles prior to second hydroprinting. Due to the complete dissolution of the sacrificial layer during the hydroprinting process, the conductive bridge-line was free from any isolating layer, thus, enabling the connectivity of the two terminals, which were located on an uneven topography (FIGS. 5A, B and D). The hydroprinting of the NFC antenna opens the door for fabrication of sensors and electronic devices directly onto 3D structures, that is essential for communication between objects, in view of the emerging field of Internet of Things (IoT). Based on the measured resistance of the antenna in FIG. 5D, the induction was calculated to be 2.34 μH.

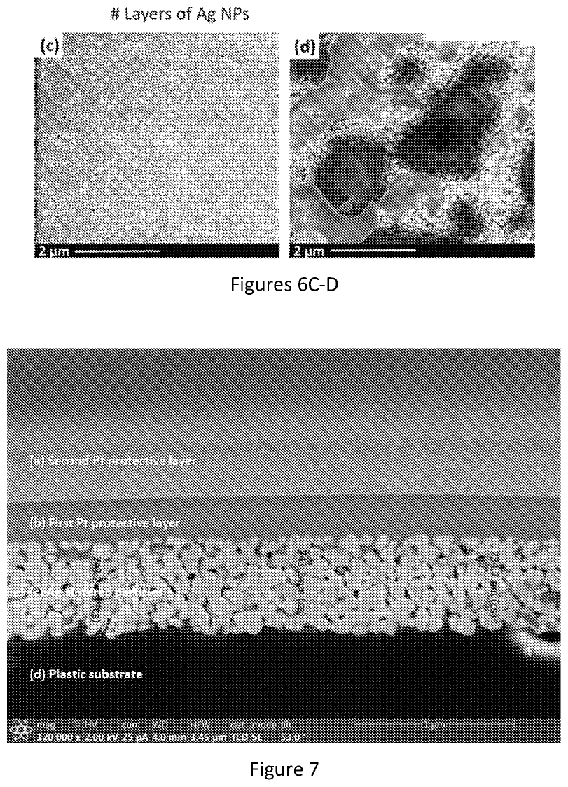

It was observed that during dissolution of the PVA film, cracks in the printed patterns may occur, causing an increase of the electrical resistance. The cracking can be prevented by modifying either the parameters (mainly the dot-per-inch, DPI) or by increasing the amount of silver NP through printing more layers on the PVA film. FIG. 6A shows the resistance change in hydroprinted patterns as a function of number of layers printed on the PVA and the DPI. As shown, the resistance decreases with the number of layers while the effect is most pronounced for the first layers printed with 600 DPI mode. The resistivity could be expected to be linearly proportional to the number of printed layers, however the results indicate that there are other parameters than the amount of silver, such as dissolution and removal of nonconductive dispersants present in the inks. It should be noted that printing of multiple layers can also improve maintaining the integrity of the printed pattern during the PVA dissolution.

In order to evaluate the resistivity of the hydroprinted lines, the height was measured from a cross section of the lines (FIG. 7), by using a focused ion beam (FIB). It was found that the average height was 864 nm (±12.8), and the calculated resistivity of 27.16 μΩcm. This is times the bulk resistivity of Ag, 1.59 μΩcm, and considered suitable for many applications. Further improvement in resistivity can be probably obtained by additional post printing processes that are suitable for 3D structures such as plasma treatment

It should be noted that the hydro-printing process has to be performed with 2D printed patterns that are sintered prior to the PVA dissolution step, otherwise the silver NPs in the pattern start to re-disperse within the aqueous bath. To overcome this, the sintering and dissolution of the PVA may be performed simultaneously, by immersing the object in an NaCl solution instead of just water (the NaCl causes the chemical sintering). In order to evaluate this possibility, the hydro-printing process was performed in aqueous solutions of NaCl at various concentrations (FIG. 6B).

As shown, conductive lines were obtained already with 0.05 wt % NaCl solution. The resistance was further decreased when dipping in a solution of 1 wt % NaCl, but above that concentration the resistance started to slightly increase. This small increase in resistance could be attributed to the presence of NaCl particles on top of the surface of the metallic pattern and in between the sintered particles. The presence of salt particles was confirmed by energy dispersive x-ray spectroscopy (EDX) and can be clearly seen in FIG. 6D.

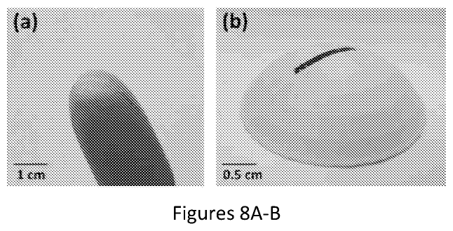

Overall, the results show that it is indeed possible to combine sintering and immersion processes. However, it seems that as soon as the printed PVA film is immersed in the solution, some of the silver NPs, which are not sintered yet by the chloride ions in the solution, begin to re-disperse in the immersion bath. This causes the pattern to start to break up, making the process less environmentally friendly. In this context, it is worth noting that a quantitative adhesion test was performed according to ISO 2409 standard tape test with 6 parallel cross cuts. A square of two by two cm sintered pattern was hydroprinted onto Vero-matte substrate. The resulting adhesion was classified as class 2, which is considered good adhesion. It is further worth noting that the versatility of the process was demonstrated by successful hydroprinting of other materials, namely CNTs and silver nanowires onto plastic objects (as shown in FIG. 8).

### Experimental Section

Water-soluble PVA film preparation: 13,000-23,000 MW PVA (Sigma-Aldrich), glycerol (Sigma-Aldrich), and a wetting agent BYK 348 (BYK Chemie) were mixed at a ratio of 15:3:0.1 respectively in deionized water at 85° C. for 2 hours, until the solution was homogeneous. A thin wet film of-120 jxm was formed by draw-down coating (RK Print-Coat Instruments, 120 μm bar) of 10 ml solution on a 125-jxm-thick polyethylenephtalate (PET) (Jolybar ltd., Israel) substrate. After overnight drying at ambient humidity and temperature, a PVA film of 35-μm average thickness was obtained, capable of dissolving in water within 2 minutes at 50° C.

Inkjet printing, sintering and sample preparation: 2D pattern printing was performed with a Dimatix inkjet printer, with a 10 pL print head (Dimatix, Fuji-Film). The ink used was Ag NP conductive ink that contained 20 wt % silver NPs (Xjet ltd., Israel). The substrate temperature was 60° C. and the substrate-printhead gap, was 1.2 mm. After printing, sintering was obtained by exposing the printed pattern to 37% hydrochloric acid vapors (Sigma-Aldrich) for 20 seconds. When the printed pattern comprises more than one free-standing line, after the 2D printing, a very thin transparent film was formed by spraying a 10 wt % PVB (Piolorfom BL 18)-ethanol solution over the pattern. This aided in keeping the gap between the lines after PVA elimination. Other polymers can be used as well, including such that can be removed after the hydroprinting.

Hydroprinting: Two methods were used for hydroprinting of conductive patterns: the object was placed above the floating pattern and immersed in it from above (FIG. 1), or the object was placed at the bottom of the water bath and the water level was lowered until the bottom side of the pattern makes contact with the object's top surface.

Using the method shown in FIG. 1, the PVA's hydrophilic polymer was placed on the water interface, and after about 2 minutes the object was carefully immersed through the printed pattern which was floating on top of the water bath. The pattern precisely adheres to the angles and shape of the object. Next, the object was pulled out of the water bath and left to fully dry in a 60° C. oven. Finally, the object was re-immersed for two minutes in a water bath to remove all PVA residues. During the immersion step, the object was oriented such that air bubbles could not become trapped between the printed pattern and the object's surface. A typical PVA film required approximately 2 minutes to fully dissolve. When hydroprinting a single line, an object could remain immersed until the PVA was fully dissolved and dried; no washing step was necessary. For hydroprinting complex patterns with multiple lines, after the object was placed at the bottom of the water bath, the PVA film was carefully placed on the water-air interface. The water was then slowly drained out of the system with a vacuum pump, until the water level with the floating PVA film makes contact with the object, and the film gently wraps itself around the object.

Demonstration of sequential overlapping transfer: Scheme of the process shown in FIG. 4B. The first line was hydroprinted and dried at 120° C. for 35 minutes, and the process is repeated twice more such that one edge of the pattern overlapped with the previous hydroprinted line (FIG. 4A).

Conductivity measurement: For measuring the effect of line conductivity on the number of layers (FIG. 6A), line patterns measuring forty by one mm were sintered and hydroprinted.

Three samples with the same number of layers were measured for resistance, and the process was repeated for lines printed with 3, 5, 7, and 9 layers. All measurements were repeated three times with resolutions of 400, 500, and 600 DPI. After the substrate was fully dried, a conductive silver paste was placed on the line, and the resistance was measured for 1 cm line, by a two-point milliohm meter (Lutron Electronic M0-2002).

NaCl sintering: Sodium chloride (Sigma Aldrich) water solution was used as the immersion liquid, at 50° C. Initial sintering was performed by immersing the printed pattern in the solution, followed by a 2.5-minute wash in the same bath after drying. This process was performed with hydroprinted patterns in NaCl at concentrations of 0.05, 0.1, 0.5, 1, 1.5, and 2 wt %. The resistance measurement was performed as described previously.

3D printing of objects: The objects used for the hydro-printing demonstration were printed with three different printers. The white dome and the wave structure (FIGS. 3D and 3E) were printed by an FDM Makerbot printer loaded with 1.75 mm of ABS filament. The spheres were printed by an Objet 30 printer loaded with Vero blue ink. The squares and other shapes in FIG. 3 were printed using the same printer, loaded with Vero white ink, all with a glossy finish. The white spheres were printed using a powder binder printer (Projet 160,3D system USA). In order to show the adhesion to two types of surfaces, one sphere was fully glued using epoxy resin and the other sphere was left with the powder-like surface.

Resistivity measurement: In order to estimate resistivity, it was necessary to measure the hydroprinted pattern thickness. An FIB was used to cut a cross section (FIG. 7). The sample was coated with two layers of platinum in order to protect the Ag pattern surface from amorphization by the intense ion beam. A low energetic electron beam was used to fabricate the first titanium layer −300 nm thick. Next, a second micron thick titanium layer was fabricated using a high energy ion beam. Last, an intense penetrate ion beam was used to cut a cross section through the Ag pattern. Height was measured with the FIB camera, which was tilted at a 53° angle. Cross-section height measurements were repeated in three randomly selected places.

Resistivity was calculated by p=Rsh, where p is resistivity, Rs is sheet resistance, and h is height.

Adhesion test: Adhesion rating based on ISO 2409 standard tape test was done according to the peeled fraction from the substrate, and classified by zero to five scale. Zero value indicates excellent adhesion (no detachments) and 5 value indicates a poor adhesion (more than 65% detachments).

1. A process for fabricating a conductive pattern on a three-dimensional (3D) object, the process comprising printing a 2-dimensional (2D) conductive planar pattern on a surface region of a 2D sacrificial substrate, causing said sacrificial substrate to decompose on a surface of a liquid, and contact-transferring said conductive pattern to a surface region of a 3D object such that the 2D conductive pattern aligns with features on the surface region of the 3D object.

2. The process according to claim 1, wherein the process is repeated two or more times to thereby contact-transfer a further pattern, optionally conductive, onto a surface region of the 3D object.

3. The process according to claim 1, wherein the printing of a 2D conductive planar pattern comprises printing a 2D non-conductive planar pattern and subsequently rendering it conductive.

4. The process according to claim 1, the process comprising:
printing on a 2D sacrificial substrate a conductive pattern having a layout alignment of surface features to a surface region of a 3D object to be associated with said pattern; said conductive pattern comprising at least one conductive material;
placing the printed sacrificial substrate onto a surface of a liquid, the liquid being selected to interact with the sacrificial substrate and cause its dissolution or decomposition, such that the conductive pattern remains intact on the surface of the liquid; and
contacting said conductive pattern with the 3D object permitting the conductive pattern to three-dimensionally align and associate with its surface.

5. The process according to claim 1, the process comprising obtaining a sacrificial substrate and printing thereon a pattern, the pattern having a layout enabling alignment of surface features to a surface region of a 3D object to be associated with said pattern.

6. The process according to claim 5, wherein the pattern is a non-conductive pattern and the process further comprises sintering the non-conductive pattern under conditions permitting coalescence of the non-conductive material, rendering the pattern conductive.

7. The process according to claim 1, wherein the pattern is formed of a material selected from the group consisting of carbon nanotubes (CNT), graphene, conductive polymers and quantum dots (QDs), and wherein the process is optionally absent of a sintering step.

8. The process according to claim 1, wherein the pattern is a transparent electrode(s) formed of a material selected from the group consisting of carbon nanotubes (CNT), sintered metal nanoparticles, conductive polymers and quantum dots (QDs).

9.-11. (canceled)

12. The process according to claim 1, the process comprising:
printing on a 2D sacrificial substrate a non-conductive pattern having a layout alignment of surface features to a surface region of a 3D object to be associated with said pattern;
causing said non-conductive pattern to be conductive;
placing the printed sacrificial substrate onto a surface of a liquid, the liquid being selected to interact with the sacrificial substrate and cause its dissolution or decomposition, such that the conductive pattern remains intact on the surface of the liquid; and
contacting said conductive pattern with the 3D object permitting the conductive pattern to three-dimensionally align and associate with its surface.

13. The process according to claim 1, the process comprising:
printing on a 2D sacrificial substrate a non-conductive pattern having a layout alignment of surface features to a surface region of a 3D object to be associated with said pattern;
placing the printed sacrificial substrate onto a surface of a liquid, the liquid being selected to interact with the sacrificial substrate and cause its dissolution or decomposition, such that the conductive pattern remains intact on the surface of the liquid;
prior to complete dissolution or decomposition, causing said non-conductive pattern to be conductive; and
contacting said conductive pattern with the 3D object permitting the conductive pattern to three-dimensionally align and associate with its surface.

14. The process according to claim 1, wherein conductivity is achieved by sintering a non-conductive pattern by treating the non-conductive pattern with a sintering agent or under sintering conditions when the patterned substrate is not floating on the liquid surface, or when the patterned substrate is on the liquid surface.

15. The process according to claim 1, wherein the sacrificial substrate is of a material selected from polymers, water-soluble materials, organic liquid soluble solids and ionic materials, or wherein the substrate is optionally selected amongst heat-sensitive plastic substrates.

16.-18. (canceled)

19. The process according to claim 15, wherein the sacrificial substrate is composed of a water-soluble material, optionally polymeric.

20.-22. (canceled)

23. The process according to claim 1, comprising printing on a sacrificial substrate a non-conductive pattern having a layout alignment of surface features to a surface region of a 3D object to be associated with said pattern; the printing is performed while the substrate is optionally on a surface of a liquid; and subsequently rendering the nonconductive pattern conductive.

24. The process according to claim 23, wherein the sacrificial substrate is placed on a surface of a liquid and the pattern is thereafter formed.

25. The process according to claim 1, wherein the pattern is formed by nonimpact printing.

26. (canceled)

27. The process according to claim 25, wherein printing comprises jetting an ink formulation comprising at least one metal nanoparticle or at least one conductive material.

28.-30. (canceled)

31. The process according to claim 1, wherein the conductive pattern is formed by patterning the sacrificial surface with a non-conductive metallic pattern and rendering the metallic pattern continuous and electrically conductive.

32. The process according to claim 31, wherein conductivity is rendered by sintering the metallic pattern by exposing the pattern to a sintering agent or to sintering conditions.

33.-45. (canceled)

46. A 3D object formed according to the process of claim 1.

47.-48. (canceled)
